(19) United States
(12) Patent Application Publication
(10) Pub. No.: US 2013/0082278 A1
(43) Pub. Date: Apr. 4, 2013

(54) NITRIDE SEMICONDUCTOR DEVICE AND METHOD FOR PRODUCING THE SAME

(71) Applicant: Sumitomo Electric Industries, Ltd., Osaka-shi (JP)

(72) Inventor: Shinya MIZUNO, Osaka-shi (JP)

(73) Assignee: Sumitomo Electric Industries, Ltd., Osaka-shi (JP)

(21) Appl. No.: 13/630,666

(22) Filed: Sep. 28, 2012

(30) Foreign Application Priority Data
Sep. 29, 2011 (JP) 2011-215422

(51) Int. Cl. H01L 21/205; H01L 29/20

(52) U.S. Cl. 257/76; 438/493; 257/E21.108; 257/E29.089

(57) ABSTRACT

A nitride semiconductor device and a method to produce the same are disclosed. The method includes steps of sequentially growing a channel layer and a first layer with bandgap energy Eg greater than that of channel layer; forming a gate replica on the first layer; selectively growing a second layer with Eg also greater than or equal to Eg of the channel layer; removing the gate replica to form a recess in the second layer; and forming the gate electrode in the recess and onto the first layer.

### BACKGROUND OF THE INVENTION

1. Field of the Invention

The present invention relates to an arrangement of a nitride semiconductor device and a method for producing the nitride semiconductor device.

2. Related Background Arts

A nitride semiconductor device such as GaN-HEMT (High Electron Mobility Transistor) has been well known and practically used as a device operable in high frequencies and high voltages. An integrated device including an enhance mode FET (E-MODE FET) and a depletion mode FET (D-MODE FET) has been reported.

Because a HEMT made of nitride semiconductor materials inherently shows the D-MODE characteristics due to the spontaneous polarization that generates excess carriers in the channel layer, a conventional GaN-HEMT forms a gate electrode thereof by etching a doped layer that supplies carriers into a channel layer to obtain a practical threshold characteristic. The process to etch the doped layer potentially causes a large scattering in the threshold voltage of the device. Moreover, when an E-MODE FET is required in such an arrangement, the doped layer is necessary to be formed thin enough, or the integration of an E-MODE FET with a D-MODE FET becomes hard enough, or almost impossible.

### SUMMARY OF THE INVENTION

One aspect of the present application relates to a method to produce a nitride semiconductor device. The method includes steps to grow a channel layer and a first layer sequentially on a substrate, wherein the channel layer and the first layer are made of nitride semiconductor materials but bandgap energy (hereafter denoted as Eg) of the first layer is greater than that of the channel layer; to form a gate replica on a portion the first layer where a gate electrode of the device is to be formed; to grow a second layer selectively in a portion on the first layer where the gate replica is not formed, where the second layer is also made of nitride semiconductor material and Eg thereof is greater than or equal to Eg of the channel layer; to remove the gate electrode to form a recess in the second layer; and to form the gate electrode on the first layer within the recess of the second layer. Because no etching process is used to form the gate electrode in an embodiment of the invention, the threshold voltage of a HEMT device is precisely determined only by controlling a thickness of the first layer.

The gate replica of the embodiments is made of silicon oxide (SiO₂) or silicon nitride (SiN) and the step of removing the gate replica is carried out by wet-etching not to influence an etching damage to the first layer.

The method may further include a process of, after removing the gate replica but before forming the gate electrode, forming a passivation layer on the second layer and a portion of the first layer exposed in the recess, and removing a portion of the passivation layer, where the gate electrode is to be formed, selectively to the first layer and the second layer to expose the first layer where the gate replica is removed and the second layer where the gate replica is not formed. Thus, the embodiment of the application forms an E-MODE FET and a D-MODE FET at the same time, where the E-MODE FET has the gate electrode on the first layer, while, the D-MODE FET has the other gate electrode on the second layer, without performing any etching for the first layer and the second layer.

Another aspect of the application relates to an arrangement of a nitride semiconductor device that includes a channel layer made of nitride semiconductor material on the substrate, a first layer also made of nitride semiconductor material with Eg greater than the Eg of the channel layer, a second layer also made of nitride semiconductor material with Eg greater than or equal to the Eg of the channel layer, and the gate electrode provided on the first layer within a recess of the second layer.

In one modification of the device, a width of the recess formed in the second layer is greater than a width of the gate electrode formed within the recess. That is, any portions of the gate electrode are apart from the second layer, which may suppress parasitic capacitance potentially caused between the gate and the second layer.

In a still another modification of the embodiment, the nitride semiconductor device has another gate electrode on the second layer. The former gate electrode on the first layer configures an E-MODE FET, while, that latter gate electrode on the second layer configures a D-MODE FET. Thus, the device of the embodiment integrates an E-MODE FET with a D-MODE FET each having a channel layer common to each other.

### BRIEF DESCRIPTION OF THE DRAWINGS

The invention will be described in conjunction with the accompanying drawings, in which:

FIG. 1 schematically shows a cross section of a nitride semiconductor device according to the first embodiment of the invention;

FIGS. 2A to 2C show processes to produce the device of the first embodiment shown in FIG. 1;

FIGS. 3A and 3B show processes subsequent to that shown in FIG. 2C;

FIG. 4 schematically shows a cross section of another nitride semiconductor device according to the second embodiment of the invention;

FIGS. 5A to 5C show processes to produce the device of the second embodiment shown in FIG. 4;

FIGS. 6A and 6B show processes subsequent to that shown in FIG. 5C;

FIG. 7 schematically shows a cross section of the nitride semiconductor device according to the third embodiment of the invention;

FIGS. 8A to 8C show processes to produce the device of the third embodiment shown in FIG. 7;

FIGS. 9A and 9B show processes subsequent to that shown in FIG. 8C;

FIG. 10 shows a circuit diagram of a DCFL inverter that implements the nitride semiconductor device of the third embodiment shown in FIG. 7; and

FIG. 11 shows a circuit diagram of a switching circuit implementing with the DCFL inverter shown in FIG. 10.

### DESCRIPTION OF PREFERRED EMBODIMENTS

Next, some preferred embodiments according to the present invention will be described as referring to drawings. In the description of the drawings, the numerals or symbols same or similar to each other will refer to the elements same or similar to each other without overlapping explanations.

### First Embodiment

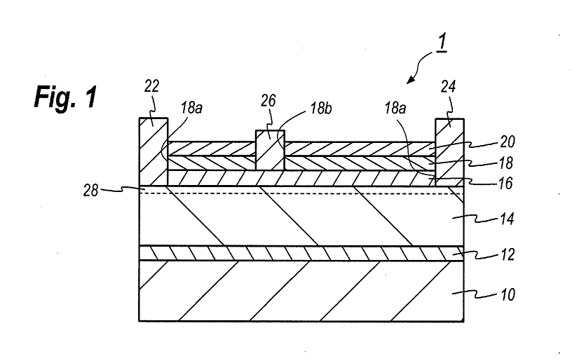

The first embodiment concentrates of an FET with the configuration of the D-MODE FET. FIG. 1 shows a cross section of a semiconductor device 1 according to the first embodiment of the invention. Referring to FIG. 1, the device 1 includes, on a substrate 10 made of SiC, a buffer layer 12, a channel layer 14, a first layer 16, a second layer 18 also, and a passivation layer 20 in this order. These layers from the buffer layer 12 to the second layer 18 are made of nitride semiconductor materials. In the present embodiment, the buffer layer 12 is made of AlN with a thickness of 300 nm, the channel layer 14 is made of GaN with a thickness of 1000 nm, the first layer is made of AlGaN with aluminum (Al) composition of 25% and a thickness of 25 nm, the second layer 18 is also made of AlGaN with Al composition of 25% and a thickness of 25 nm, and the passivation layer 20 is made of silicon nitride (SiN).

A first recess 18a penetrates, from the surface of the passivation layer 20, to the top of the channel layer 14 via the passivation layer 20, the second layer 18 and the first layer 16. Source and drain electrodes, 22 and 24, fill the first recess. The source and drains electrodes, 22 and 24, come in contact with the top of the channel layer 14. In the present embodiment, the source and drain electrodes stacks metals of tantalum (Ta) and aluminum (Al), where Ta is in contact with the channel layer 14. Anther recess 18b is formed between the source and drain electrodes to penetrate the passivation layer 20 and the second layer 18. A gate electrode 26 fills this latter recess 18b to come in contact with the top of the first layer. The gate electrode 26 stacks metals of nickel (Ni) and gold (Au), where Ni is in contact with the first layer 16.

The first and second layers, 16 and 18, operate as a doped layer to supply carriers, electrons in the present embodiment, to the channel layer 14, which forms the two-dimensional electron gas (hereafter denoted as 2DEG) in the interface between the first layer 16 and the channel layer 14, specifically, in the side of the channel layer 14 at the interface. The gate electrode 26 controls the flow of electrons in the 2DEG from the source electrode 22 to the drain electrode 24, which realizes the HEMT. Setting the thickness of the first layer 16, which is set to be 25 nm in the present embodiment, the HEMT shows the D-MODE characteristic.

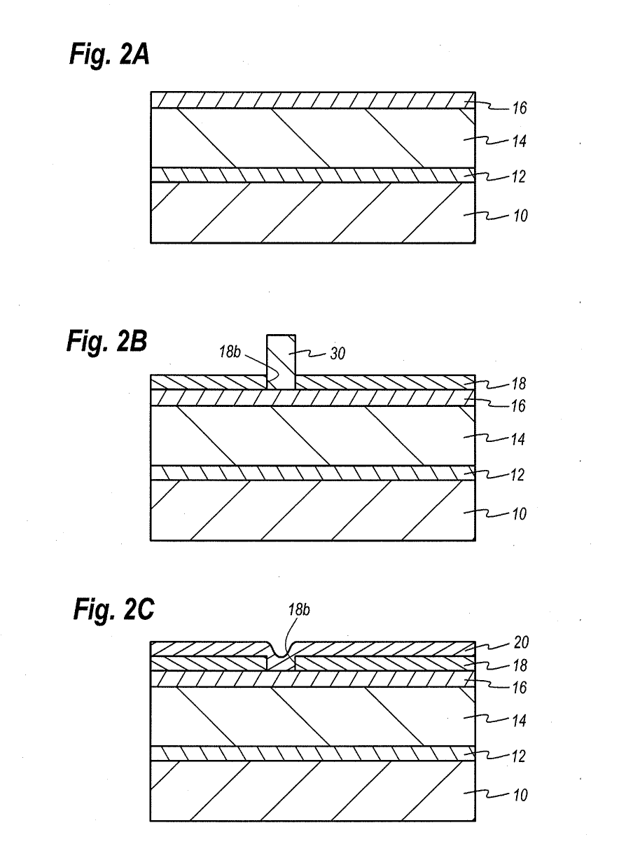

Next, a method of producing the D-MODE FET shown in FIG. 1 will be descried. Figs. from 2A to 3B show cross sections of the D-MODE FET at respective steps of the production. Referring to FIG. 2A, the process first grows from the buffer layer 12 to the first layer 16 sequentially by, what is called, the metal organized chemical vapor deposition (hereafter denoted as MOCVD) technique. The growth conditions of the layers, 12 to 16 are summarized in table 1. In the MOVPE technique, the source gases are carried commonly by hydrogen (H) for the growth of all layers.

TABLE 1
Growth conditions of layers 12-14

| | | |
|---|---|---|
| buffer layer | source gases: | tri-methyl-aluminum (TMA) |
| | | ammonia (NH₃) |
| | temperature: | 1000° C. |
| | thickness: | 300 nm |
| channel layer | source gases: | tri-methyl-gallium (TMG) |
| | temperature: | 1000° C. |
| | thickness: | 1000 nm |
| first layer | source gases: | TMA, TMG, NH₃ |
| | temperature: | 1000° C. |
| | Al composition: | 25% |
| | thickness: | 25 nm |

Because the first layer 16 is made of AlGaN with Al composition of 25%, the Eg thereof is greater than that of the channel layer 14 made of GaN.

Then, the process forms a gate replica 30 on the first layer 16. Specifically, an insulating film made of silicon oxide (SiO₂) is first deposited on the surface of the first layer 16 by the conventional sputtering technique; then, a portion of the insulating film except for an area where the gate electrode 26 is finally to be formed therein is removed.

Then, the MOCVD technique selectively grows the second layer 18 made of AlGaN in the area where the insulating film is removed. The second layer 18 comes in contact with the top of the first layer 16. The growth conditions of the second layer 18 are shown in the next table 2.

TABLE 2
Growth conditions of the second layer 18

| | | |
|---|---|---|
| second layer | source gases: | TMA, TMG, NH₃ |
| | temperature: | 1000° C. |
| | Al composition: | 25% |
| | thickness: | 25 nm |

Because the second layer 18 is made of AlGaN, the Eg thereof is also greater than that of the channel layer 14 made of GaN.

Referring to FIG. 2C, the gate replica 30 is fully etched by an etchant including fluoric acid (HF) to leave a recess 18b in the second layer 18 and to expose the surface of the first layer 16. Then, another insulating film 20 operating as the passivation layer made of silicon nitride (SiN) in the present embodiment covers a whole of the surfaces of the second layer 18 and the first layer 16 exposed in the recess 18b. As illustrated in FIG. 2C, the insulating film 20 fully covers the exposed first layer 16 in the recess 18b.

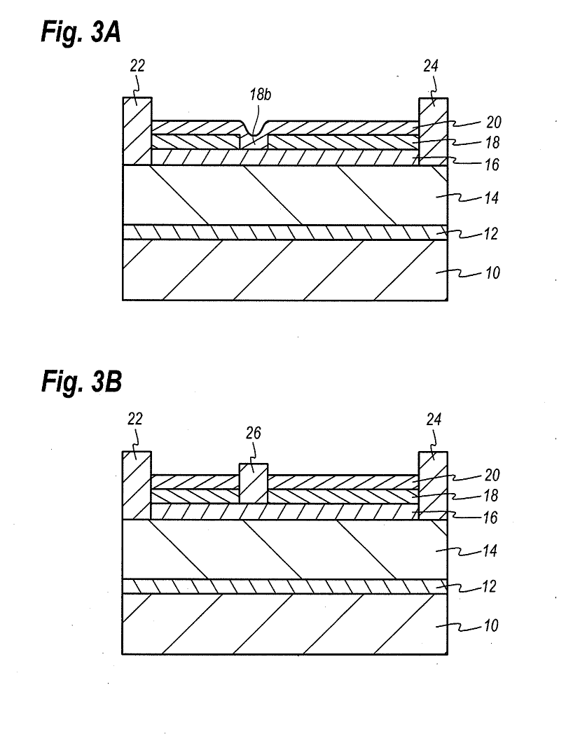

Referring to FIG. 3A, the source and drain electrodes, 22 and 24, are formed. Specifically, another insulating film made of SiO₂ first covers the passivation layer 20, then, a portion of this insulating film corresponding to areas where the source and drain electrodes is to be formed, is removed to expose the passivation film 20. Then, the passivation layer 20, the second layer 18, and the first layer 16 are sequentially removed by, for instance, a dry-etching process to from the recess 18a that exposes the top of the channel layer 14. The reactive gas to etch the passivation layer 20 made of SiN may contain fluorine (F), for instance, CF₄, CHF₃, C₂F₆, SF₆ and so on; while the reactive gas for etching the first layer 16 and the second layer 18 each made of AlGaN may contain chlorine (Cl), for instance, Cl₂, BCl₃, SiC₄, and so on. Then, the metal evaporation accompanied with a subsequent lift-off technique forms the metal stack of tantalum (Ta) and aluminum (Al) for the source 22 and the drain 24 electrodes.

Referring to FIG. 3B, the process further deposits another mask layer made of, for instance, silicon dioxide (SiO₂) and patterns this SiO₂ so as to expose the top of the passivation layer 20 in a portion where the gate electrode 26 is to be formed. The dry etching using a reactive gas containing fluorine (F) etches the passivation layer 20 to expose the top of the first layer 16. The evaporation and the subsequent lift-off technique form a metal stack of nickel (Ni) and gold (Au) for the gate electrode 26.

Thus, the first embodiment forms the gate replica 30 in an area where the gate electrode is to be formed after growing the channel layer 14 and the first layer 16 on the substrate 10. Then, the second layer 18 is selectively grown in an area except for the gate replica 30. Removing the gate replica 30, the gate electrode 26 is formed on the first layer 16; the semiconductor device 1 shown in FIG. 1 is completed. The semiconductor device 1 provides the channel layer 14 and the first layer 16 sequentially on the substrate 10, and two second layers 18 separated to each other on the first layer 16. The gate electrode 26 is provided between thus separated second layers 18 such that the gate electrode 26 is buried by the second layer 18. Thus, the buried gate electrode 26 may be formed without etching a layer with a function to supply carriers into the channel layer 14. In the present embodiment, such a layer to supply carriers is the second layer 18 provided on the first layer 16.

In a conventional technique to form the buried gate electrode, the stack of the layers including the first layer 16 and also the second layer 18 is first grown. Then, etching a portion of the second layer 18, the gate electrode may be formed to be buried in this portion of the second layer 18. The second layer may be etched by a reactive gas containing chlorine (Cl), which is hard to secure the etching ratio between the first layer 16 and the second layer 18. The first layer 16 is often etched by the dry-etching of the second layer 18, which forces the thickness of the first layer 16 left by the etching to be scattered and the threshold characteristic of the device 1 becomes uncontrollable. While, the present embodiment selectively grows the second layer 18 on the first layer 16 without etching the second layer 18; and the gate electrode is buried in the portion where the second layer 18 is not grown, which leaves the thickness of the first layer 16 unchanged and the threshold characteristic of the device 1 may be precisely controlled.

Moreover, the selective growth of the second layer 18 may enhance the thickness thereof except for a portion of the gate electrode 26, which enables to increase the carrier concentration of the 2DEG 28 and reduces the parasitic resistance thereof. Still further, the 2DEG 28 in a region except for just beneath the gate electrode 26 may be apart from the second layer 18, which equivalently means that the 2DEG 28 is apart from traps caused in the surface of the second layer 18; accordingly, the current collapsing due to the traps may be reduced.

The gate replica 30 is preferably removed by the wet-etching selectively to the first layer 16 and the second layer 18. The selective etching means that the etching rate of the gate replica 30 is far greater than that of the first layer 16 and the second layer 18. The selective etching may substantially prevent the first and second layers, 16 and 18, from being etched during the etching of the gate replica 30, which may precisely control the thickness of the first layer 16 just beneath the gate electrode 26. Thus, the gate replica 30 is preferably made of SiN in order to secure a larger rate of the wet-etching.

The passivation layer 20 covers the second layer 18. When the second layer 18 contains aluminum (A), for instance, the second layer is made of AlGaN, the second layer 18, in particular, aluminum (Al) atoms contained therein, is easily oxidized to form aluminum oxide (Al₂O₃), which increases the parasitic resistance of the device. The passivation layer 20 covering the second layer 18 may effectively prevent the device from degrading.

The passivation layer 20 covering the second layer 18 is removed in a portion where the gate electrode 26 is to be formed by the dry-etching to secure the dimensional accuracy of, for instance, the width of the gate electrode. Because the passivation layer 20 is made of SiN, the dry-etching using a gas containing fluorine (F) which shows a large etching rate for SiN against those of the first and second layers, 16 and 18. That is, the first and second layers, 16 and 18, are hardly etched and the threshold characteristic of the device may be stabilized.

### Second Embodiment

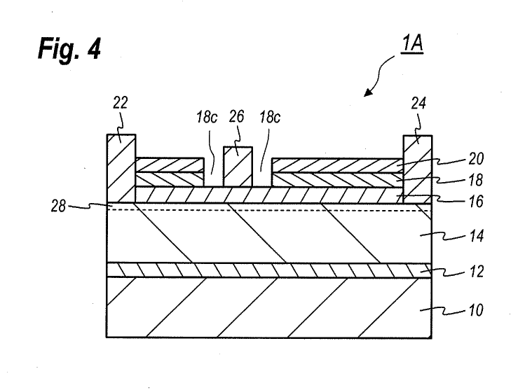

The second embodiment according to the present invention relates to an arrangement of a semiconductor device 1A that buries the gate electrode in a wide recess. FIG. 4 shows a cross section of the device of the second embodiment. Referring to FIG. 4, one of features of the present embodiment distinguishable from those of the first embodiment is that the gate electrode 26 is buried in a wide recess 18c; specifically, the gate electrode 26 in side walls thereof is apart from the second layer 18. Other arrangements are the same with those of the first embodiment.

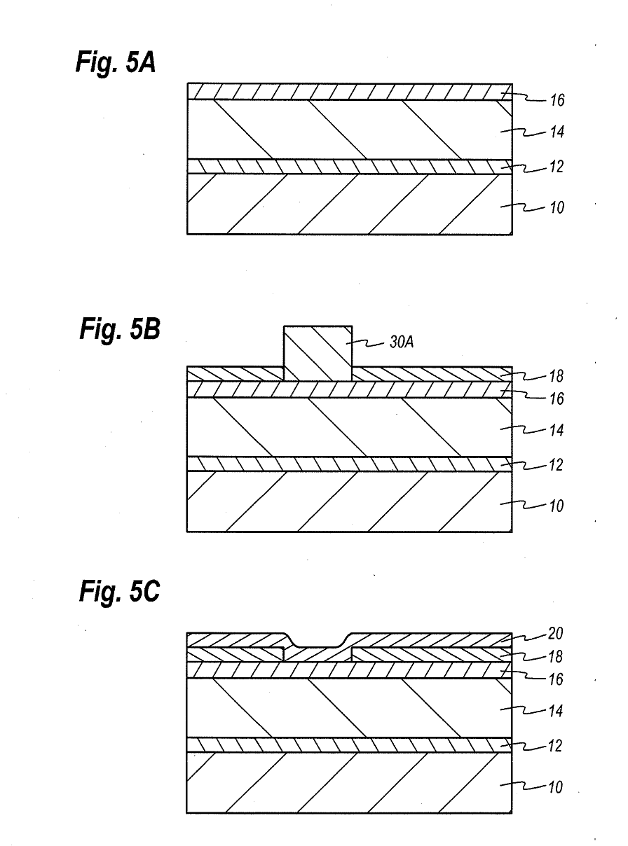

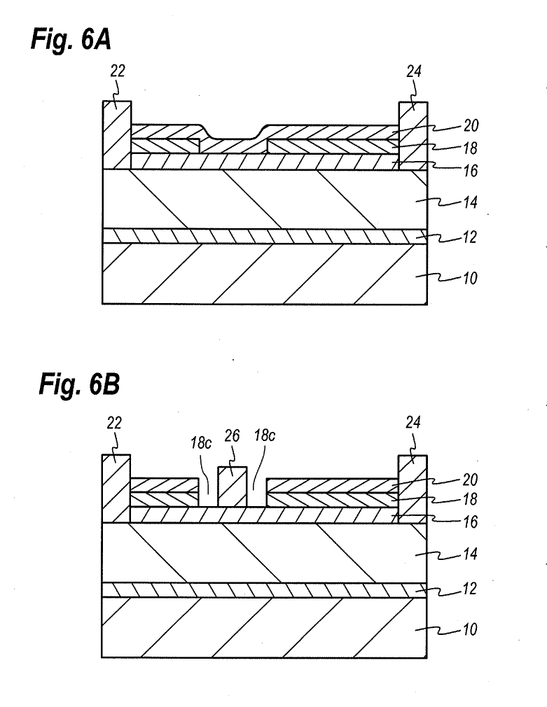

A method to form the device 1A of the second embodiment will be described. Figures from FIG. 5A to FIG. 6B each show a process to form the device. Referring FIG. 5A, the process grows semiconductor layers from the buffer layer 12 to the first layer 16 on the semiconductor substrate 10 by the MOCVD technique. Conditions to grow the layers, 12 to 16, are the same as those shown in table 1.

Then, the process forms an inorganic film made of silicon oxide (SiO₂) by, for instance, sputtering and removes thus formed SiO₂ film except for an area with a width wider than a width of the gate to be formed. That is, a mesa stripe made of SiO₂ along the area where the gate electrode is formed is left on the first layer 16. This mesa stripe operates as the gate replica 30A. The, process selectively grows the second layer 18 by the MOCVD technique. The growth conditions of the second layer 18 are the same as those shown in Table 2.

Selectively removing the gate replica 30A against the first and second layers, 16 and 18, by the wet-etching, the passivation layer 20 covers not only the whole surface of the second layer 18 but the first layer 16 exposed in the bottom of the recess 18c formed by the second layer 18. Referring to FIG. 6A, removing the passivation layer 20, the second layer 18 and the first, layer in portions where the source and drain electrodes are formed to form recesses, the process stacks metals for the source and drain electrodes, 22 and 24, within the recesses.

Referring to FIG. 6B, the process then forms a wide recess 18c by removing only a portion of the passivation layer 20 not covering the second layer 18, in other words, a portion coming in contact with the first layer 16, by dry-etching. Then, the gate electrode 26 is formed with the recess 18c. As shown in FIG. 6B, the wide recess 18c has a width wider than a width of the gate electrode 26.

Thus, the second embodiment of the invention forms the gate replica 30A with the width wider than the width of the gate electrode 26. This gate replica 30A operates as a mask for the selective growth of the second layer 18, that is, the second layer 18 is grown on the first layer 16 not covered by the gate replica 30A. The gate electrode 26 is formed, after removing the gate replica 30A, so as not to come in contact with the second layer 18. When the gate electrode 26 in the sides thereof comes in contact with the second layer 18; parasitic capacitance, the gate-source capacitance or the gate-drain capacitance, unintentionally increases. The arrangement of the gate electrode 26 of the present embodiment effectively suppresses the increase of the gate capacitance.

The first layer 16 and the second layer 18 in respective embodiments of the invention are made of AlGaN with aluminum (Al) composition of 25%; but, those layers are not restricted to those conditions. The first layer 16 is requested to have a unique condition that the first layer 16 is made of nitride semiconductor material with Eg greater than that of the channel layer 14. Similarly, the second layer 18 is also requested to be made of nitride semiconductor material with Eg greater than or equal to that of the channel layer 14.

For instance, when the channel layer 14 is made of GaN, combinations of the first and second layers, 16 and 18, are available of AlGaN and GaN, InAlN and InAlN, and so on, where table 3 below shows some combinations of the first and second layers, 16 and 18, including examples above described.

TABLE 3
Combinations of layers

| | case 1 | case 2 | case 3 | case 4 | case 5 |
|---|---|---|---|---|---|
| second layer | AlGaN | GaN | AlGaN | GaN | InAlN |
| first layer | AlGaN | AlGaN | AlGaN | AlGaN | InAlN |
| spacer | — | — | AlN | AlN | AlN |
| channel layer | GaN | GaN | GaN | GaN | GaN |

Referring to Table 3, when the first and second layers, 16 and 18, are made of AlGaN and GaN, respectively, namely, the cases 2 and 4; the first layer 16 operates as a doped layer to supply electrons in the channel layer 14 while the second layer 18 operates as a cap layer to protect the first layer 16. In these cases, the first layer 16 has a thickness of about 25 nm for the device to have the threshold voltage of the D-MODE configuration. The second layer 18 has a thickness of 5 nm. A spacer layer made of AlN may be put between the channel layer 14 and the first layer 16 as cases 3 and 4 in table 3. The AlN spacer layer has a thickness of about 1 nm, which induces a large discontinuity in the conduction band between the channel layer 14 and the space layer, which increases the carrier density in the 2DEG. Thus, AlN spacer layer may realize the high current density and high power of the device 1A.

Case 5 in table 3 provides, in addition to AlN spacer, the InAlN first layer 16 and the InAlN second layer 18. Two InAlN layers, 16 and 18, may operate as a doped layer to supply carriers into the channel layer 14 as those in cases 1 and 3. The AlN spacer layer has a thickness of about 1.5 nm, while, the InAlN first layer 16 has a thickness of 3.5 nm and the InAlN second layer 18 has a thickness of 10 nm to show the D-MODE threshold characteristic of the device 1A.

A HEMT has a superior characteristic in a high speed operation because of substantially no scattering of carriers in the 2DEG. However, a HEMT inherently shows an inferior characteristic in a high power operation because of lesser number of carriers in the 2DEG because of the dimensionality thereof. Accordingly, a HEMT is continuously requested to enhance the carrier concentration in the 2DEB. For AlGaN doped layer, a greater composition of aluminum (Al) may increase the carrier concentration in the 2DEG, but such an AlGaN layer also enhances the lattice mismatching against GaN channel layer, which degrades the crystal quality and causes the scattering of carriers in the 2DEG. On the other hand, when an InAlN is applied to the doped layer, not only the lattice mismatching of InAlN with GaN may be resolved but two materials induce a greater discontinuity in the conduction band due to a large difference in the spontaneous polarization, which results in the 2DEG with a higher carrier concentration. Moreover, AlN spacer layer physically separates the 2DEG from impurities doped in InAlN doped layer, which reduces the ion scattering in the 2DEG and enhances the mobility thereof.

The first and second embodiments concentrates on conditions for the D-MODE FET; however, a device with an enhanced MODE (E-MODE) is available by adjusting the thickness of the first layer 16 beneath the gate electrode 26.

### Third Embodiment

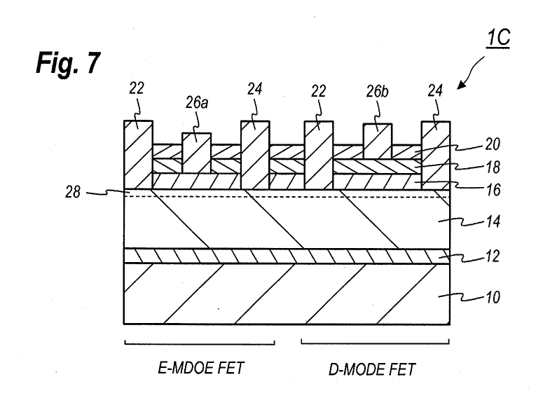

A semiconductor device 1C according to the third embodiment of the invention will be next described. FIG. 7 shows a cross section of the device 1C that integrates an E-MODE FET with a D-MODE FET on a common substrate. Referring to FIG. 7, the device has features distinguishable from the first embodiment that the device has the first layer 16 made of AlN with a thickness of 1.5 nm and the second layer 18 made of InAlN with aluminum (Al) composition of 17% and a thickness of 3.5 nm; and the D-MODE FET provides the source, drain and gate electrodes, 22 to 24, while, the E-MODE FET also provides the source, drain and gate electrodes, 22 to 26, where the gate electrode of the D-MODE FET, which has the symbol of 26a, comes in contact with the first layer 16, while, that of the D-MODE FET, which is indicated as 26b, is provided on the second layer 18. Other arrangements are substantially same as those appeared in the device of the first embodiment and omitted in the explanations thereof.

A method to form the device 1C of the third embodiment will be described. Figs. from 8A to 9B show respective steps of the process of forming the semiconductor device 1C of the third embodiment. The process first grows semiconductor layers from the buffer layer 12 to the first layer 16 on the substrate 10 by the MOCVD technique. The growth conditions of the layers, 12 to 16, are shown in table 4 below, where those of the buffer layer 12 and the channel layer 14 are same with those of the first embodiment shown in table 1. Because the first layer 16 is made of AlN having Eg greater than that of GaN, the first layer 16 operates as a spacer layer.

TABLE 4
growth conditions of layers of third embodiment

| | | |
|---|---|---|
| buffer layer | source gases: | TMA, NH₃ |
| | temperature: | 1000° C. |
| | thickness: | 300 nm |
| channel layer | source gases: | TMG, NH₃ |
| | temperature: | 1000° C. |
| | thickness: | 1000 nm |
| first layer | source gases: | TMA, NH₃ |
| | temperature: | 1000° C. |
| | thickness: | 1.5 nm |
| second layer | source gases: | Tri-Methyl-Indium (TMI), |
| | | TMA, NH₃ |
| | temperature: | 800° C. |
| | In composition: | 17% |
| | thickness | 3.5 nm |

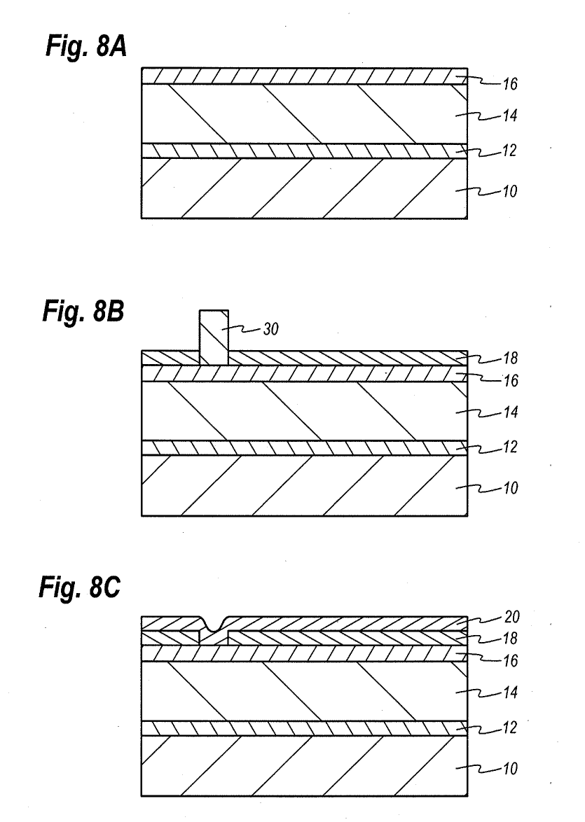

The process then forms a gate replica 30 for the E-MODE FET. Specifically, depositing an insulating film made of SiO₂ on the first layer 16, and patterning this insulating film to leave a portion thereof on an area where the gate electrode 26a is to be formed, the gate replica 30 is formed on the first layer 16, as shown in FIG. 8B. Then, the second layer 18 is selectively grown on the first layer 16 by the conditions shown in table 4. The second layer 18, which is made of InAlN, has Eg greater than that of GaN channel layer 14 and operates as a doped layer to supply carriers to the channel layer 14.

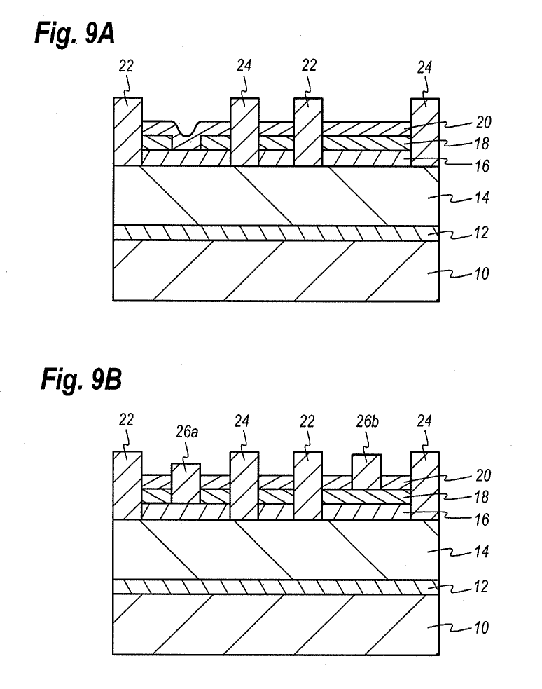

The process then removes the gate replica 30 by wet-etching selectively against the first and second layers, 16 and 18. Then, a passivation layer 20 covers the top surface of the second layer 18 and that of the first layer 16 exposed within the recess in the second layer 18 as shown in FIG. 8C. Referring to FIG. 9A, the source and drain electrodes, 22 and 24, for the E-MODE FET and the D-MODE FET are subsequently formed. Specifically, portions of the passivation layer 20, the second layer 18, and the first layer 16, where the source and drain electrodes are to be formed, is sequentially etched by using reactive gas containing fluorine (F) for the passivation layer 20 and that containing chlorine (Cl) for the second and first layers, 18 and 16. Then, a metal stack fills within thus etched portions for the source and drain electrodes, 22 and 24.

Then, the gate electrodes, 26a and 26b, are formed. Specifically, a portion of the passivation layer 20, where the gate electrode 26a for the E-MODE FET and the other gate electrode 26b for the D-MODE FET are to be formed, is removed by the dry-etching using a gas containing fluorine (F), then, the electrode 26a for the E-MODE FET fills thus formed recess to come in contact with the first layer 16, at the same time, the other electrode 26b for the D-MODE FET fills another recess to come in contact with the second layer 18.

The device 1C according to the third embodiment, the gate replica 30 is first formed in an area on the first layer 16 where the gate electrode 26 for the E-MODE FET is to be formed, and the second layer 18 is selectively grown on the first layer 16. Removing the gate replica 30 and filling the recess with the gate electrode 26a, the E-MODE FET is completed. On the other hand, the gate electrode 26b for the D-MODE FET is formed directly on the second layer 18. This arrangement, where the gate 26a is on the first layer 16 while the other gate 26b is on the second layer 18, makes the threshold voltage of the D-MODE FET greater than that of the E-MODE FET. Thus, the third embodiment of the invention facilitates the integration of the E-MODE FETs with the D-MODE FETs. Moreover, the. gate electrodes, 26a and 26b, for respective types of the FETs may be formed in the same time.

The first and second layers, 16 and 18, of the device according to the third embodiment are made of AlN and InAlN, respectively, where the indium (In) composition thereof is 17%; however, materials for respective layers, 16 and 18, are not restricted to the combination above described. The first layer 16 preferably has Eg greater than that of the channel layer 14, while, the second layer 18 preferably has Eg thereof equal to or greater than that of the channel layer 14. Various combinations shown in table 5 are considered for to the device 1C. The first and second layers, 16 and 18, may be made of AlGaN, which corresponds to case 2 in table 5. In this case, both of the first and second layers, 16 and 18, operate as a doped layer to supply carriers into the channel layer 14. The first layer preferably has a thickness of about 8 nm and an aluminum (Al) composition of 25%, while, the second layer has a thickness of 17 nm and the aluminum composition (Al) of 25%.

Case 3 shown in table 5 is also applicable to two layers, 16 and 18; that is, the first layer is made of AlGaN, while, the second layer is made of GaN. In the arrangement of case 3, the first layer 16 operates as a doped layer to supply carriers into the channel layer, while, the second layer 18 made of GaN operates as a cap layer to protect the first layer 16. The first layer 16 preferably has a thickness of 8 nm and aluminum (Al) composition of 25%; while, the second layer 18 made of GaN has a thickness of 5 nm.

TABLE 5
Combinations of layers

| | case 1 | case 2 | case 3 |
|---|---|---|---|
| second layer | InAlN | AlGaN | GaN |
| first layer | AlN | AlGaN | AlGaN |
| channel layer | GaN | GaN | GaN |

As already explained, the dry-etching removes the passivation layer 20 by using a reaction gas containing fluorine (F), which enhances a difference of the etching rate for the passivation layer 20 against the first layer 16 and the second layer 18. The first and second layers, 16 and 18 are hard to be etched. Accordingly, the threshold voltage of the E-MOE FET and that of the D-MODE FET, which depends on a thickness of layers left beneath the gate electrodes, 26a and

[symbol]

The device according to the first to third embodiments provides the passivation layer 20 made of silicon nitride (SiN); however, the passivation layer 20 is not restricted to this material. Any material able to be etched selectively against the first and second layers, 16 and 18, is applicable to the passivation layer 20. Also, as shown in tables 3 and 5, the first layer operates as the spacer layer or the doped layer to supply carriers into the channel layer 14, while, the second layer 18 operates as the doped layer or a cap layer. Specifically, when the first layer 16 operates as the doped layer, the second layer operates as the doped layer or the cap layer; on the other hand, when the first layer 16 operates as the spacer layer, the second layer 18 operates as the doped layer.

The first to third embodiments provide the semiconductor substrate 10 made of SiC, the device of the embodiments may have another type of substrate, for instance, a substrate made of silicon (Si), that made of GaN substrate, that made of a sapphire, or that made gallium oxide (Ga₂O₃). Moreover, other source materials are applicable to the epitaxial growth of semiconductor layers, for instance, tri-ethyl-aluminum (TEA) and tri-ethyl-gallium (TEG) are applicable for aluminum (Al) source and gallium (Ga) source, respectively. The technique to grow semiconductor layers is also not restricted to the MOCVD; other techniques such as molecular beam epitaxy (MBE) are also used for the epitaxial grown of the layers.

### Fourth Embodiment

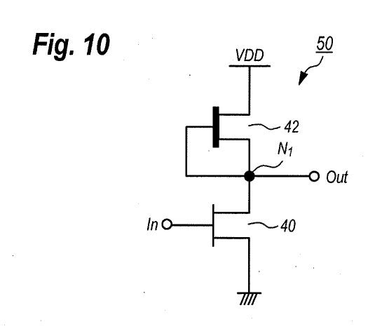

The fourth embodiment according to the present invention relates to an electronic circuit that applies the device 1C of the third embodiment to a switching circuit. FIG. 10 shows an inverter circuit of the present embodiment that includes an E-MODE FET 40, in which the source thereof is grounded, the gate receives an input signal, and the drain is connected to the node N₁ to provide an output signal, and a D-MODE FET 42, in which the gate and the source is short-circuited to be connected the node N₁ to provide the output and the drain is biased with a power supply V_{DD}. These E-MODE FET and D-MODE FET have the arrangement of the previous embodiment. The switching circuit 50 shown in FIG. 10 constitutes the inverter of a direct coupled FET logic (DCFL).

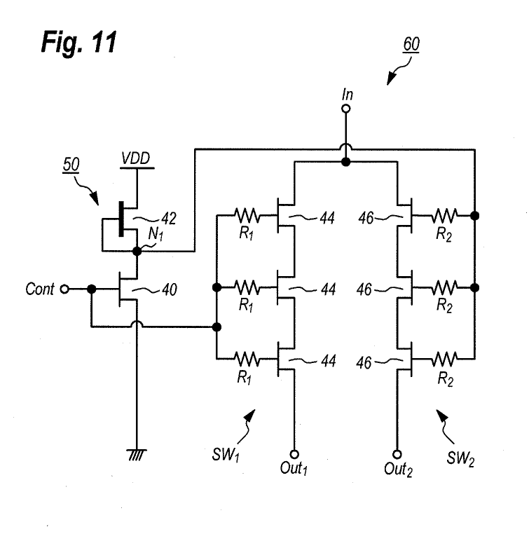

FIG. 11 shows a switching circuit 60 that implements with the DFCL 50 shown in FIG. 10. The switching circuit 60 includes the DFCL inverter 50, and two switches, SW₁ and SW₂, each of which includes three E-MODE FETs connected in series between the input In and the output, Out₁ and Out₂. The DCFL inverter 50 receives the control signal Cont in the gate of the E-MODE FET 40. When the control signal Cont becomes HIGH, three E-MODE FETs 44 in the switch SW₁ turn on, while, other E-MODE FETs 46 in the switch SW₂ turn off, which connects the input terminal In with one of the output terminal Out₁. When the control signal oppositely becomes LOW, the first SW₁ turns off, while, the second switch SW₂ turns on, which connects the input terminal In with the second output terminal Out₂.

In the foregoing detailed description, the method and apparatus of the present invention have been described with reference to specific exemplary embodiments thereof. It will, however, be evident that various modifications and changes may be made thereto without departing from the broader spirit and scope of the present invention. The present specification and figures are accordingly to be regarded as illustrative rather than restrictive.

I claim:

1. A method to produce a nitride semiconductor device, comprising steps of:
growing a channel layer made of nitride semiconductor material and a first layer sequentially on a substrate, wherein the first layer is made of nitride semiconductor material having bandgap energy greater than bandgap energy of the channel layer;
forming a gate replica on a portion of the first layer where a gate electrode is to be formed;
selectively growing a second layer in a portion on the first layer except for the gate replica, wherein the second layer is made of nitride semiconductor material having bandgap energy equal to or greater than the bandgap energy of the channel layer;
removing the gate replica to form a recess in the second layer; and
forming the gate electrode on the first layer within the recess.

2. The method of claim 1,
wherein the gate replica has a width wider than a width of the gate electrode; and
wherein the gate electrode in side walls thereof is apart from the second layer.

3. The method of claim 1,
wherein the channel layer is made of GaN, and
wherein the first layer and the second layer have one of combinations of AlGaN and AlGaN, AlGaN and GaN, InAlN and InAlN, AlN and InAlN, respectively.

4. The method of claim 1,
wherein the gate replica is made of one of silicon oxide and silicon nitride.

5. The method of claim 4,
wherein the step of removing the gate replica is carried out by an wet-etching selectively to the first layer and the second layer.

6. The method of claim 4,
further including steps of:
after removing the gate replica but before forming the gate electrode, forming a passivation layer on the second layer and a portion of the first layer exposed in the recess of the second layer; and
removing a portion of the passivation layer, where the gate electrode is to be formed, selectively to the first layer and the second layer.

7. The method of claim 6,
wherein the step of removing the portion of the passivation layer exposes the first layer where the gate replica is removed and the second layer where the gate replica is not formed.

8. The method of claim 7,
wherein the step of forming the gate electrode includes a step of forming a gate electrode on the first layer and another gate electrode on the second layer to configure an E-MODE FET and a D-MODE FET, respectively.

9. The method of claim 1,
wherein the second layer supplies carriers into the channel layer.

10. The method of claim 1,
wherein the step of growing the second layer selectively is carried out by a metal-organic chemical vapor phase deposition (MOCVD) technique.

11. A nitride semiconductor device, comprising:
a substrate;
a channel layer provided on the substrate, the channel layer being made of nitride semiconductor material;
a first layer made of nitride semiconductor material having bandgap energy greater than bandgap energy of the channel layer;
a second layer made of nitride semiconductor material having bandgap energy equal to or greater than the bandgap energy of the channel layer, the second layer providing a recess to expose the first layer therein; and
a gate electrode provided on the first layer within the recess of the second layer.

12. The device of claim 10,
wherein the channel layer is made of GaN, and
wherein the first layer and the second layer has a combination of one of AlGaN and AlGaN, AlGaN and GaN, InAlN and InAlN, AlN and InAlN, respectively.

13. The device of claim 11,
further including another gate electrode provided on the second layer.
